(19) United States
(12) Patent Application Publication
(10) Pub. No.: US 2020/0083259 A1
(43) Pub. Date: Mar. 12, 2020

(54) ARRAY SUBSTRATE, METHOD FOR FABRICATING ARRAY SUBSTRATE, AND DISPLAY

(71) Applicant: HKC CORPORATION LIMITED, Shenzhen, Guangdong (CN)

(72) Inventor: Beizhou Huang, Shenzhen, Guangdong (CN)

(21) Appl. No.: 16/312,311

(22) PCT Filed: Nov. 1, 2018
(86) PCT No.: PCT/CN2018/113397

§ 371 Date: Dec. 21, 2018

(30) Foreign Application Priority Data
Sep. 11, 2018 (CN) 201811054834.5

(51) Int. Cl. H01L 27/12; H01L 29/417

(52) U.S. Cl. CPC H01L 27/1248; H01L 29/41733; H01L 27/1259

(57) ABSTRACT

An array substrate includes a substrate, a gate electrode, a gate insulating layer, an active layer, a source-drain electrode, and a passivation layer. A buffer layer is disposed between the source-drain electrode and the passivation layer for improving the adhesion between the source-drain electrode and the passivation layer, and the buffer layer is coated on the surface of the source-drain electrode.

### CROSS-REFERENCE TO RELATED APPLICATIONS

This application is the International Application No. PCT/CN2018/113397 for entry into US national phase with an international filing date of Nov. 1, 2018, designating US, now pending, and claims priority to Chinese Patent Application No. 201811054834.5, filed on Sep. 11, 2018, the content of which is incorporated herein by reference in its entirety.

### BACKGROUND

### Technical Field

The present application pertains to the technical field of display, and particularly relates to an array substrate, a method for fabricating an array substrate, and a display.

### Description of Related Art

With the increasingly progress of the display technologies, the panel display has become one of the indispensable necessities for people. At present, the mainstream display includes an active matrix liquid crystal display (AMLCD) and an active matrix organic light emitting diode (AMOLED) display, and the two display modes coexist with each other with their respective advantages.

The AMLCD comprises an active array substrate, a color filter substrate and a liquid crystal layer between the two substrates. The AMOLED display includes an active array substrate and an organic light emitting diode layer. Both display modes require a stable and reliable array substrate. The array substrate includes one or more thin-film transistors (TFTs), and as people's demand for the resolution of the display panel and the display quality is increasing, the materials of the conductive layer and the insulating layer, and the fabricating method of the TFTs, compared with conventional ones, start to change. For example, the conventional Al/Mo material begins to turn to material such as Cu/Mo, Cu/Mo—Ti, ITO, etc., or silicon nitride, silicon oxide or other organic or inorganic insulating materials. However, as the material changes, the source-drain electrode of the conductive layer and the passivation (PV) layer tend to produce poor adhesion, which not only reduces the yield of finished products, but also affects the display quality. For example, when the source-drain electrode is a wire made of Cu and the PV layer is made of silicon oxide, the adhesion between the source-drain electrode and silicon oxide is poor, and gas bulging occurs, which greatly reduces the yield of the panel.

### SUMMARY

The purpose of the present application is to overcome the above-mentioned deficiencies of the prior art, and to provide an array substrate, a method for fabricating an array substrate, and a display, which are intended to include, but are not limited to solve the technical problem of poor adhesion between a source drain and a passivation layer in an array substrate including a TFT in the prior art.

In order to achieve the above purpose, the technical solutions adopted by the present application are as follows:

An array substrate, which includes:

a substrate;

a gate electrode formed on the substrate;

a gate insulating layer, which is formed on the substrate and covers the gate electrode;

an active layer formed on the gate insulating layer;

a source-drain electrode formed on the active layer; and

a passivation layer covering the source-drain electrode;

wherein a buffer layer is disposed between the source-drain electrode and the passivation layer for improving the adhesion between the source-drain electrode and the passivation layer, and the buffer layer is coated on the surface of the source-drain electrode.

In an embodiment, the buffer layer is made of a conductive material, and the conductive material is ITO, molybdenum alloy or titanium-contained alloy.

In an embodiment, the buffer layer is made of a semiconductor material, and the semiconductor material is a metal oxide semiconductor material.

In an embodiment, the buffer layer is made of a insulating material, and the insulating material is an organic insulating material or an inorganic insulating material.

In an embodiment, the organic insulating material is resin.

In an embodiment, the inorganic insulating material includes at least one of silicon nitride, silicon oxynitride and aluminium oxide.

A method for fabricating an array substrate, which includes the following steps of:

providing a substrate;

preparing a gate electrode on the substrate;

preparing a gate insulating layer on the gate electrode;

preparing an active layer 4 on the gate insulating layer;

preparing a source-drain electrode on the active layer; and

preparing a buffer layer on the source-drain electrode, and preparing a passivation layer on the buffer layer;

wherein the buffer layer is coated on the surface of the source-drain electrode, and the buffer layer is configured for improving the adhesion between the source-drain electrode and the passivation layer.

In an embodiment, the buffer layer is made of a conductive material, a semiconductor material, or an insulating material.

In an embodiment, the buffer layer has a thickness of 10-200 nm.

At last, the present application provides a display, which includes an array substrate, and the array substrate includes:

a substrate;

a gate electrode formed on the substrate;

a gate insulating layer, which is formed on the substrate and covers the gate electrode;

an active layer formed on the gate insulating layer;

a source-drain electrode formed on the active layer; and

a passivation layer covering the source-drain electrode;

wherein a buffer layer is disposed between the source-drain electrode and the passivation layer for improving the adhesion between the source-drain electrode and the passivation layer, and the buffer layer is coated on the surface of the source-drain electrode;

the buffer layer is made of an insulating material, and the insulating material is an organic insulating material or an inorganic insulating material; the organic insulating material is a resin, and the inorganic insulating material comprises at least one of silicon nitride, silicon oxynitride and aluminum oxide.

In an embodiment, the display is a LCD or an OLED display.

In the array substrate provided by an embodiment of the present application, a buffer layer is added between the source-drain electrode and the passivation layer, and the buffer layer is coated on the surface of the source and drain electrodes and has good adhesion for the source-drain electrode and the passivation layer at same time, so that the adhesion between the source-drain electrode and the passivation layer can be improved. Compared with the prior art, the array substrate with the buffer layer provided by the present application has a good flatness and uniformity, which can improve the phenomenon such as the presence of bubbles during the displaying process of the display panel, as well as uneven display of bright spots or dark spots or the like.

In the method for fabricating an array substrate provided by an embodiment of the present application, the buffer layer is directly added between the source-drain electrode and the passivation layer for improving the adhesion between the source-drain electrode and the passivation layer, and the buffer layer is coated on the surface of the source-drain electrode to completely enclose the source-drain electrode. The preparation process does not require the cost for an additional mask, and therefore, the process is simple and the cost is low, and the finally obtained array substrate has good flatness and uniformity, which can significantly improve the phenomenon of uneven displaying during the displaying process of the display panel, such as the presence of bubbles, and bright spots or dark spots and the like.

The display provided by the embodiment of the application is provided with the array substrate unique to the present application, and the array substrate has good flatness and uniformity, which can improve the phenomenon of uneven displaying of the display panel during the displaying process, such as the presence of bubbles, and bright spots or dark spots, so the display having the array substrate has a good displaying effect.

### BRIEF DESCRIPTION OF THE DRAWINGS

In order to more clearly illustrate the technical solutions in the embodiments of the present application, the drawings used in the description of the embodiments or the prior art will be briefly described below. Obviously, the drawings in the following description are merely some embodiments of the present application, and other drawings may be obtained based on these drawings for those of ordinaries skilled in the art without inventive work.

FIG. 1 is an effect diagram of abnormity caused by poor adhesion between a source-drain electrode and a passivation layer of a current array substrate.

FIG. 2 is a structural diagram of the array substrate provided by an embodiment of the present application, in which a buffer layer is added between the source-drain electrode and the passivation layer.

Herein, the reference signs in the drawings are as follows:
substrate; 2—gate electrode; 3—gate insulating layer; 4—active layer; 5—source-drain electrode; 6—passivation layer; 7—buffer layer.

### DESCRIPTION OF THE EMBODIMENTS

In order to make the technical problems, technical solutions and advantages of the present application more clear, the present application will be further described in detail below with reference to the accompanying drawings and embodiments. It should be understood that, the specific embodiments described herein are merely illustrative of the application and are not intended to limit the application.

It should be noted that, when an element is referred to as being “fixed” or “disposed” to another element, the element may be directly on another element or indirectly on another element. When an element is referred to as being “connected” to another element, the element may be directly connected to another element or indirectly connected to another element.

It should be understood that, the orientation and position relationship indicated by the terms “length”, “width”, “upper”, “lower”, “front”, “back”, “left”, “right”, “vertical”, “horizontal”, “top”, “bottom”, “inside”, “outside” and the like are based on the orientation or position relationship as shown in the drawings, and are merely for convenience of description of the present application and simplifying description, and do not indicate or imply the indicated device or component must have a particular orientation, be constructed or operated in a particular orientation, and thus are not to be construed as limiting the present application.

Moreover, the terms “first” and “second” are merely used for descriptive purposes and are not to be construed as indicating or implying a relative importance or implicitly indicating the amount of technical features indicated. Thus, the feature defined with “first” or “second” may include one or more of the features either explicitly or implicitly. In the description of the present application, “a plurality of” means two or more unless specifically defined otherwise.

In one aspect, an embodiment of the present application provides an array substrate, the structure of which is as shown in FIG. 2, and the array substrate includes:

a substrate 1;

a gate electrode 2 formed on the substrate 1;

a gate insulating layer 3, which is formed on the substrate 1 and covers the gate electrode 2;

an active layer 4 formed on the gate insulating layer 3;

a source-drain electrode 5 formed on the active layer 4; and

a passivation layer 6 covering the source-drain electrode 5;

wherein a buffer layer 7 is disposed between the source-drain electrode 5 and the passivation layer 6 for improving the adhesion between the source-drain electrode 5 and the passivation layer 6, and the buffer layer 7 is coated on the surface of the source-drain electrode 5.

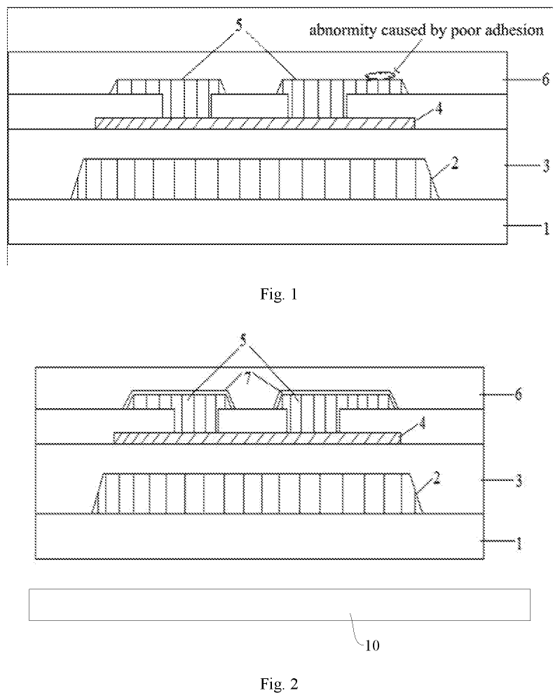

FIG. 1 is a structural schematic view of a conventional array substrate, in which the adhesion between the source-drain electrode 5 (such as Cu) and the passivation layer 6 (such as silicon oxide) is poor, and gas swell occurs. However, in the array substrate provided by an embodiment of the present application (as shown in FIG. 2), a buffer layer 7 is added between the source-drain electrode 5 and the passivation layer 6, and the buffer layer 7 is coated on the surface of the source and drain electrodes 5 and has good adhesion for the source-drain electrode 5 and the passivation layer 6 at same time, so that the adhesion between the source-drain electrode 5 and the passivation layer 6 can be improved. Therefore, the array substrate with the buffer layer 7 provided by the embodiment of the present application has a good flatness and uniformity, which can improve the phenomenon such as the presence of bubbles during the displaying process of the display panel, as well as uneven display of bright spots or dark spots or the like.

Further, in the array substrate provided by an embodiment of the present application, the buffer layer 7 is composed of any one of a conductive material, a semiconductor material or an insulating material, that is to say, the buffer layer 7 may be a conductive layer composed of a conductive material, or may be a semiconductor layer composed of a semiconductor material, or may be an insulating layer composed of an insulating material.

Alternatively, the buffer layer is composed of a conductive material, and the conductive material is indium tin oxide (ITO), an alloy containing molybdenum (Mo) or an alloy containing titanium (Ti). Alternatively, the buffer layer is composed of a semiconductor material, and the semiconductor material is a metal oxide semiconductor material such as zinc oxide, tin oxide, indium oxide, molybdenum oxide or the like, or a mixture thereof. Alternatively, the buffer layer is composed of an insulating material, and the insulating material is an organic insulating material or an inorganic insulating material; wherein the inorganic insulating material includes at least one of silicon nitride, silicon oxynitride, and aluminum oxide (since the problem that the adhesion between the passivation layer composed of the silicon oxide material and the source-drain electrode composed of the Cu material is not good is to be solved, the material of the buffer layer does not include silicon oxide herein); the organic insulating material is a resin, and the resin includes various natural resins and artificial resins, such as phenol resin, urea resin, aniline formaldehyde resin, melamine formaldehyde resin, glycerin resin, silicone resin, polyester film, unsaturated polyester resin, epoxy resin and the like.

The reasons for the poor adhesion between the passivation layer composed of the silicon oxide material and the source-drain electrode composed of the Cu material lie in that: the silicon oxide (SiOx) has fewer surface defects, and suspended Si— is relatively small, so that there are less suspended Si— bonds bonded to the surface of Cu having a face-centered cubic structure, and good adhesion is less likely to occur. The conductor material and the semiconductor material are connected by an ionic bond, which can be in good contact with the surface of Cu; and the organic material such as the resin can also be in good contact with the surface of Cu due to the special thermal expansion coefficient and the van der Waals force that may exist. Therefore, the buffer layer composed of the above materials can increase the adhesion between the passivation layer and the source-drain electrode.

In a specific embodiment, the source-drain electrode 5 is made of a Cu material, and the source-drain electrode 5 is provided with a channel above the active layer 4, and the source-drain electrode 5 is divided into a source electrode and a drain electrode, which are respectively distributed on two sides of the active layer 4. The passivation layer 6 is made of silicon oxide, and the buffer layer 7 may be selected as an ITO layer. The oxide conductor ITO layer is added on the surface of Cu to solve the problem of poor adhesion between Cu and silicon oxide. Meanwhile, the wet etching line width Loss of the metal wire (such as Cu) of the source-drain electrode 5 is larger than that of the oxide conductive material ITO, therefore, the metal wire of the source-drain electrode 5 and the ITO layer (the buffer layer 7) may not only use the same photomask, but the ITO may cover the metal surface of the source-drain electrode 5 to form a protective layer of the source-drain electrode 5.

Further, in the array substrate provided by an embodiment of the present application, the thickness of the buffer layer 7 ranges from 10-200 nm. Within this thickness range, not only the adhesion between the source-drain electrode is increased, but also the displaying performance of the display panel will not be affected, thus the comprehensive effect is the best.

In another aspect, an embodiment of the present application further provides a method for fabricating an array substrate, and the method includes the following steps of:

S01: providing a substrate 1;

S02: preparing a gate electrode 2 on the substrate 1;

S03: preparing a gate insulating layer 3 on the gate electrode 2;

S04: preparing an active layer 4 on the gate insulating layer 3;

S05: preparing a source-drain electrode 5 on the active layer 4; and

S06: preparing a buffer layer 7 on the source-drain electrode 5, and preparing a passivation layer 6 on the buffer layer 7;

wherein the buffer layer 7 is coated on the surface of the source-drain electrode 5, and the buffer layer 7 is configured for improving the adhesion between the source-drain electrode 5 and the passivation layer 6.

In the method for fabricating an array substrate provided by an embodiment of the present application, the buffer layer 7 is directly added between the source-drain electrode 5 and the passivation layer 6 for improving the adhesion between the source-drain electrode 5 and the passivation layer 6, and the buffer layer 7 is coated on the surface of the source-drain electrode 5 to completely enclose the source-drain electrode. The preparation process does not require the cost for an additional mask, and therefore, the process is simple and the cost is low, and the finally obtained array substrate has good flatness and uniformity, which can significantly improve the phenomenon of uneven displaying during the displaying process of the display panel, such as the presence of bubbles, and bright spots or dark spots and the like.

Further, the substrate 1 is a glass substrate, and the prepared gate insulating layer 3 (GI) may be made of silicon nitride or silicon oxide. The prepared active layer 4 is a structure of an etching stop layer (ESL), and specifically may be an a-Si layer. The prepared buffer layer 7 is composed of a conductive material, a semiconductor material or an insulating material, and the buffer layer has a thickness of 10-200 nm. The buffer layer 7 in the fabrication method has been described in detail in the above array substrate, and the description of which will not be repeated here.

At last, an embodiment of the present application provides a display, which includes an array substrate, and the array substrate includes:

a substrate 1;

a gate electrode 2 formed on the substrate 1;

a gate insulating layer 3, which is formed on the substrate 1 and covers the gate electrode 2;

an active layer 4 formed on the gate insulating layer 3;

a source-drain electrode 5 formed on the active layer 4; and

a passivation layer 6 covering the source-drain electrode 5;

wherein a buffer layer 7 is disposed between the source-drain electrode 5 and the passivation layer 6 for improving the adhesion between the source-drain electrode 5 and the passivation layer 6, and the buffer layer 7 is coated on the surface of the source-drain electrode 5;

the buffer layer 7 is composed of an insulating material, and the insulating material is an organic insulating material or an inorganic insulating material; the organic insulating material is a resin, and the inorganic insulating material includes at least one of silicon nitride, silicon oxynitride and aluminum oxide.

The display provided by the embodiment of the application is provided with the array substrate unique to the present application, and the array substrate has good flatness and uniformity, which can improve the phenomenon of uneven displaying of the display panel during the displaying process, such as the presence of bubbles, and bright spots or dark spots, so the display having the array substrate has a good displaying effect.

Further, the display is a liquid crystal display, which may be selected as an active liquid crystal display; or the display is an organic light emitting diode display, which may be selected as an active organic light emitting diode display. That is to say, the active liquid crystal display includes the array substrate, the color filter substrate and the liquid crystal layer between the two substrates in the embodiments of the present application, and the organic light emitting diode display including the array substrate and the organic light emitting diode layer in the embodiments of the present application.

The present application has been tested several times in succession, and a part of the test results are now described in further detail as a reference, which will be described in detail below in conjunction with specific embodiments.

One of the Embodiments

FIG. 2 is the structural schematic view of the array substrate including a plurality of TFTs of an embodiment of the present application, and the array substrate includes: a substrate 1 made of glass material; a gate electrode 2 formed on the substrate 1; a gate insulating layer 3, which is formed on the substrate 1 and covers the gate electrode 2; an active layer 4 formed on the gate insulating layer 3; a source-drain electrode 5 made of Cu material and formed on the active layer 4; and a passivation layer 6, which is made of silicon oxide material and covers the source-drain electrode 5; wherein a buffer layer 7 made of ITO material is disposed between the source-drain electrode 5 and the passivation layer 6 for improving the adhesion between the source-drain electrode 5 and the passivation layer 6, and the buffer layer 7 is coated on the surface of the source-drain electrode 5.

The process of fabricating the array substrate is as follows:

S11: providing a substrate 1 made of glass;

S12: preparing a gate electrode 2 on the substrate 1;

S13: preparing a gate insulating layer 3 (GI) on the gate electrode 2;

S14: preparing an active layer 4 on the gate insulating layer 3;

S15: preparing a source-drain electrode 5 (Cu material) on the active layer 4; and

S16: preparing a buffer layer 7 (ITO layer) on the source-drain electrode 5, and preparing a passivation layer 6 (PV, silicon oxide material) on the buffer layer 7;

wherein the buffer layer 7 is coated on the surface of the source-drain electrode 5, and the buffer layer 7 is configured for improving the adhesion between the source-drain electrode 5 and the passivation layer 6, and solving the poor adhesion between Cu and silicon oxide.

Another One of the Embodiments

FIG. 2 is the structural schematic view of the array substrate including a plurality of TFTs of an embodiment of the present application, and the array substrate includes: a substrate 1 made of glass material; a gate electrode 2 formed on the substrate 1; a gate insulating layer 3, which is formed on the substrate 1 and covers the gate electrode 2; an active layer 4 formed on the gate insulating layer 3; a source-drain electrode 5 made of Cu material and formed on the active layer 4; and a passivation layer 6, which is made of silicon oxide material and covers the source-drain electrode 5; wherein a buffer layer 7 made of organic insulating material or inorganic insulating material is disposed between the source-drain electrode 5 and the passivation layer 6 for improving the adhesion between the source-drain electrode 5 and the passivation layer 6, and the buffer layer 7 is coated on the surface of the source-drain electrode 5.

The process of fabricating the array substrate is as follows:

S21: providing a substrate 1 made of glass;

S22: preparing a gate electrode 2 on the substrate 1;

S23: preparing a gate insulating layer 3 (GI) on the gate electrode 2;

S24: preparing an active layer 4 on the gate insulating layer 3;

S25: preparing a source-drain electrode 5 (Cu material) on the active layer 4; and

S26: preparing a buffer layer 7 on the source-drain electrode 5 (organic insulating layer or inorganic insulating material), and preparing a passivation layer 6 (PV, silicon oxide material) on the buffer layer 7;

wherein the buffer layer 7 is coated on the surface of the source-drain electrode 5, and the buffer layer 7 is configured for improving the adhesion between the source-drain electrode 5 and the passivation layer 6, and solving the poor adhesion between Cu and silicon oxide.

The above description is only alternative embodiments of the present application, and is not intended to limit the present application. Various changes and modifications may be made to the present application for those of ordinaries skilled in the art. Any modification, equivalent substitution or improvement made within the spirit and principles of the present application should be included within the scope of the present application.

1. An array substrate, comprising:
a substrate;
a gate electrode formed on the substrate;
a gate insulating layer, formed on the substrate and covering the gate electrode;
an active layer formed on the gate insulating layer;
a source-drain electrode formed on the active layer; and
a passivation layer covering the source-drain electrode;
wherein a buffer layer is disposed between the source-drain electrode and the passivation layer for improving the adhesion between the source-drain electrode and the passivation layer, and the buffer layer is coated on the surface of the source-drain electrode.

2. The array substrate according to claim 1, wherein the buffer layer is made of a conductive material, and the conductive material is ITO, molybdenum alloy or titanium-contained alloy.

3. The array substrate according to claim 1, wherein the buffer layer is made of a semiconductor material, and the semiconductor material is a metal oxide semiconductor material.

4. The array substrate according to claim 1, wherein the buffer layer is made of an insulating material, and the insulating material is an organic insulating material or an inorganic insulating material.

5. The array substrate according to claim 4, wherein the organic insulating material is resin.

6. The array substrate according to claim 4, wherein the inorganic insulating material comprises at least one of silicon nitride, silicon oxynitride and aluminium oxide.

7. The array substrate according to claim 1, wherein the buffer layer has a thickness of 10-200 nm.

8. A method for fabricating an array substrate, comprising:
providing a substrate;
preparing a gate electrode on the substrate;
preparing a gate insulating layer on the gate electrode;
preparing an active layer 4 on the gate insulating layer;
preparing a source-drain electrode on the active layer; and
preparing a buffer layer on the source-drain electrode, and preparing a passivation layer on the buffer layer;
wherein the buffer layer is coated on the surface of the source-drain electrode, and the buffer layer is configured for improving the adhesion between the source-drain electrode and the passivation layer.

9. The method according to claim 8, wherein the buffer layer is made of a conductive material, a semiconductor material, or an insulating material.

10. The method according to claim 8, wherein the buffer layer has a thickness of 10-200 nm.

11. A display, comprising an array substrate, wherein the array substrate comprises:
a substrate;
a gate electrode formed on the substrate;
a gate insulating layer, which is formed on the substrate and covers the gate electrode;
an active layer formed on the gate insulating layer;
a source-drain electrode formed on the active layer; and
a passivation layer covering the source-drain electrode;
wherein a buffer layer is disposed between the source-drain electrode and the passivation layer for improving the adhesion between the source-drain electrode and the passivation layer, and the buffer layer is coated on the surface of the source-drain electrode;
the buffer layer is made of an insulating material, and the insulating material is an organic insulating material or an inorganic insulating material; the organic insulating material is a resin, and the inorganic insulating material comprises at least one of silicon nitride, silicon oxynitride and aluminum oxide.

12. The display according to claim 11, wherein the display is a LCD or an OLED display.
